(19) United States
(12) Patent Application Publication
(10) Pub. No.: US 2019/0307029 A1
(43) Pub. Date: Oct. 3, 2019

(54) Attaching a Component to a Circuit Board Using an Over-filled Cavity of Solder

(71) Applicant: Google LLC, Mountain View, CA (US)

(72) Inventors: Nael Hannan, Brentwood, CA (US); Fan Li, San Jose, CA (US)

(21) Appl. No.: 15/941,683

(22) Filed: Mar. 30, 2018

(51) Int. Cl. H05K 9/00; H05K 1/18; H05K 3/34

(52) U.S. Cl. CPC H05K 9/0028; H05K 9/0039; H05K 1/183; H05K 2203/0139; H05K 2201/10371; H05K 2201/1056; H05K 3/3452

(57) ABSTRACT

In general, the subject matter described in this disclosure can be embodied in a circuit-board attachment method. The method includes providing a circuit board that defines a channel in a surface of the circuit board, and placing a stencil over the surface of the circuit board so that a slot that is in the stencil and defined by the stencil aligns with the channel in the circuit board. The method includes applying solder to the stencil when the slot in the stencil is aligned with the channel in the circuit board to provide the solder into the slot in the stencil and the channel, and removing the stencil, leaving the solder in the channel and protruding from the channel. The method includes placing a component in contact with the solder that is protruding from the channel, and heating the solder to attach the component to the circuit board.

### TECHNICAL FIELD

This document generally relates to attaching a component to a circuit board using an over-filled cavity of solder.

### BACKGROUND

Many electronic devices include circuit boards that have electronic components mounted thereto. These electronic components are often mounted to circuit boards with solder, which provides both physical and electrical connections to the circuit boards. The electrical connections are sometimes provided to conductive traces on a surface of the circuit board, which route electrical power and/or electrical data signals to and from such electronic components.

Conductive traces often run across a top surface of the circuit board. Still, some circuit boards also include one or more layers within the circuit board through which additional conductive traces may run. In circuit boards that have multiple layers of conductive traces, the layers may be separated by an electrically insulating material, and a conductive trace on one conductive layer may electrically connect to a conductive trace on another conductive layer with a conductive “via” that extends vertically through the circuit board to electrically connect traces of different layers. Designs that use multiple layers of conductive traces can house many different electronic components in a small footprint, with at least portions of the electrical connections being buried within the interior of the circuit board.

### SUMMARY

This document describes techniques, methods, systems, and other mechanisms for attaching a component to a circuit board using an over-filled cavity of solder.

As additional description to the embodiments described below, the present disclosure describes the following embodiments.

Embodiment 1 is a circuit-board attachment method. The method comprises providing a circuit board that defines a channel in a surface of the circuit board. The method comprises placing a stencil over the surface of the circuit board so that a slot that is in the stencil and defined by the stencil aligns with the channel in the circuit board. The method comprises applying solder to the stencil when the slot in the stencil is aligned with the channel in the circuit board to provide the solder into the slot in the stencil and the channel. The method comprises removing the stencil, leaving the solder in the channel and protruding from the channel. The method comprises placing a component in contact with the solder that is protruding from the channel. The method comprises heating the solder to attach the component to the circuit board.

Embodiment 2 is the method of embodiment 1. The circuit board is a multi-layer circuit board that includes an interior conductive layer. A conductor located within the interior conductive layer runs along a bottom of the channel and defines at least a portion of the bottom of the channel.

Embodiment 3 is the method of embodiment 2. The conductor that runs along the bottom of the channel is grounded.

Embodiment 4 is the method of embodiment 1. A length of the channel is at least ten times greater than a width of the channel.

Embodiment 5 is the method of embodiment 4. The width of the channel is greater than a width of the component at a location of the channel at which the component attaches to the circuit board.

Embodiment 6 is the method of embodiment 1. Removing the stencil leaves the solder protruding from the channel beyond the surface of the circuit board by approximately a thickness of the stencil.

Embodiment 7 is the method of embodiment 1. Heating the solder attaches the component to the circuit board such that at least a portion of the component is located within the channel below the surface of the circuit board.

Embodiment 8 is the method of embodiment 1. The component comprises an electromagnetic interference shield.

Embodiment 9 is the method of embodiment 8. The channel continuously or discontinuously surrounds a region of the circuit board. Multiple sides of the electromagnetic interference shield are located in the channel so that the electromagnetic interference shield surrounds and covers the region of the circuit board that is surrounded by the channel.

Embodiment 10 is an electronic device assembly. The device assembly comprises a circuit board that defines a channel in a surface of the circuit board. The device assembly comprises a component that is attached to the circuit board, with the component being located partially in the channel and partially out of the channel. The device assembly comprises solder that attaches the component to the circuit board, with the solder being partially in the channel and partially protruding from the channel.

Embodiment 11 is the electronic device assembly of claim 10. The circuit board is a multi-layer circuit board that includes an interior conductive layer. A conductor located within the interior conductive layer runs along a bottom of the channel and defines at least a portion of the bottom of the channel.

Embodiment 12 is the electronic device assembly of claim 11. The conductor that runs along the bottom of the channel is grounded.

Embodiment 13 is the electronic device assembly of claim 10. A length of the channel is at least ten times greater than a width of the channel.

Embodiment 14 is the electronic device assembly of claim 13. The width of the channel is greater than a width of the component at a location of the channel at which the component attaches to the circuit board.

Embodiment 15 is the electronic device assembly of claim 10. The component comprises an electromagnetic interference shield.

Embodiment 16 is the electronic device assembly of claim 15. The channel continuously or discontinuously surrounds a region of the circuit board. Multiple sides of the electromagnetic interference shield are located in the channel so that the electromagnetic interference shield surrounds and covers the region of the circuit board that is surrounded by the channel.

Embodiment 17 is the electronic device assembly of claim 16. The device assembly further comprises a computer processor that is mounted to the region of the circuit board that is surrounded by the channel and the electromagnetic interference shield.

Embodiment 18 is the electronic device assembly of claim 10. The device assembly further comprises a computer processor that is mounted to the circuit board. The channel surrounds the computer processor and includes a first channel portion. The channel includes a second channel portion that is opposite and parallel to the first channel portion, the computer processor being located between the first channel portion and the second channel portion. The channel includes a third channel portion that is perpendicular to the first channel portion and perpendicular to the second channel portion. The channel includes a fourth channel portion that is perpendicular to the first channel portion, perpendicular to the second channel portion, and parallel to the third channel portion, the computer processor being located between the third channel portion and the fourth channel portion.

Embodiment 19 is the electronic device assembly of claim 18. The first channel portion connects with a first end of the third channel portion and a first end of the fourth channel portion. The second channel portion connects with a second end of the third channel portion and a second end of the fourth channel portion.

The details of one or more implementations are set forth in the accompanying drawings and the description below. Features, objects, and advantages will also be apparent from the description and drawings, and from the claims.

### DESCRIPTION OF DRAWINGS

FIGS. 1A-E show multiple cross-sectional views of a circuit board as a component is attached to the circuit board using an over-filled cavity of solder.

FIG. 2A shows a side-view of a component after the component has been attached to a circuit board using an over-filled cavity of solder.

FIG. 2B shows an example in which a connection between a circuit board and an attached component is discontinuous.

FIG. 3 shows a computing device that includes a circuit board to which a component has been attached using an over-filled cavity of solder.

FIGS. 4A-B show a flowchart of a process for attaching a component to a circuit board using an over-filled cavity of solder.

Like reference symbols in the various drawings indicate like elements.

### DETAILED DESCRIPTION

This document generally describes attaching a component to a circuit board using an over-filled cavity of solder. Attaching a component using an over-filled cavity of solder, rather than attaching the component to solder that is not deposited in a cavity, can allow the use of additional solder to connect a component to a circuit board without increasing a footprint of space on the circuit board required for attaching the component, or can allow a decrease in footprint required to attach a component.

Rather than using a stencil to apply solder to only a top surface of a circuit board (e.g., a printed circuit board) at which an electronic component may be attached, the circuit board can include a cavity and the stencil may be used to apply solder into the cavity. Using a stencil in such a manner may not only fill the cavity with solder, but can also leave solder extending out of the cavity above a surface of the circuit board by an amount approximately equal to a thickness of the stencil. A component may thereafter be placed over the channel that has the solder protruding therefrom, and heat may be applied to the solder to cause the component to settle at least partially into the channel. The solder may then cool, physically and electrically attaching the component to the circuit board in its settled position. The solder that is applied in such a process is often a flux-cored solder or a solder paste (e.g., a mixture of small solder balls in a flux), although this description will simply refer to such material as “solder” for simplicity of description.

In some examples, the component that is attached to the circuit board is an electromagnetic interference (EMI) shield that at least partially surrounds and covers electronic devices that may be sensitive to EMI. To protect such electronic devices from EMI (or to contain EMI produced by components within the EMI shield so that the EMI does not interfere with components located outside of the EMI shield), the periphery of the EMI shield may connect to the circuit board with solder to isolate the electronic devices that are surrounded by the EMI shield from EMI. Gaps in the connection between the periphery of the EMI shield and the circuit board may allow EMI to enter the interior of the EMI shield and may therefore reduce a level of protection provided by the EMI shield. As such, a computer processor located underneath the EMI shield may be more susceptible to interference. In some examples, a wireless circuit (e.g., to produce Bluetooth, WiFi, or NFC signals) may be located inside of the EMI shield.

As mentioned above, solder may be applied to a circuit board using a stencil. Stencils are often made of metal and define holes, slots, and other shapes of apertures at locations at which solder is to be applied to a corresponding circuit board. The apertures may be formed using laser cutting or electroforming, for example. The stencil may be placed over the circuit board, and solder applied to the circuit board, for example, with a squeegee that wipes solder across the stencil and deposits the solder into the apertures of the stencil. The stencil may then be removed, leaving solder at locations on the circuit board that correspond to the locations of the apertures of the stencil.

As components on circuit boards are manufactured with smaller overall dimensions to enable a reduction in the overall size of such circuit boards (or to allow more components to be attached to the circuit boards), it is also desirable to reduce the footprint occupied by the solder that connects such components to the circuit boards. This can be done by reducing the width of apertures in the stencil. A problem with simply reducing the width of apertures without reducing a thickness of the stencil, is that the solder may be more likely to “lift off” the circuit board when the stencil is removed. In other words, narrowing the width of stencil apertures without decreasing a thickness of the stencil may result in some solder sticking to the stencil rather than depositing onto a circuit board. For a long slot in a stencil designed to leave a continuous line of solder on a circuit board, any “lift off” may leave a discontinuous line of solder on the circuit board. An EMI shield attached using this discontinuous line of solder may therefore be attached with a gap in its connection to the circuit board, and this gap may negatively affect performance of the EMI shield.

A stencil that has less thickness may be used to limit the amount of solder “lift off,” but reducing the thickness of a stencil also reduces a height of the solder that is deposited onto a circuit board, which can negatively affect the attachment of some components to a circuit board. For instance, a heavier component or a vibrating component attached with a limited amount of solder may not form a sufficient structural connection with the circuit board. Also, if the component that is being attached to the circuit board is not perfectly planar at its location of attachment, only a portion of the intended attachment surface of the component may contact the solder if a relatively-thin layer of solder has been deposited.

Turning back to the above-described example of an EMI shield, some such shields are formed out of sheet metal that is bent at its edges to form side walls at which the EMI shield connects to the circuit board. The bottom edges of these side walls may not be perfectly co-planar, for example, because the sheet metal may not have been perfectly rectangular before the sheet metal was formed into the EMI shield, or because the forming of the sheet metal into the EMI shield may induce a curve to the bottom edge of a side wall that attaches to the circuit board. If the extent of this non-co-planarity of the point of attachment to the circuit board exceeds the height of solder deposited onto the circuit board, the EMI shield may attach to the circuit board with undesired discontinuities. Stated another way, if the bottom edge of component being attached to a circuit board is not sufficiently flat, only some of the bottom edge may settle into the solder and some of the bottom edge may remain suspended above the solder.

To address such discontinuities, a thicker stencil may be used so that more solder is deposited in the vertical direction on the circuit board. There are potential downsides to this approach, as described above. Another option is to add an additional layer of solder on top of the first layer of solder to increase the solder height in a two-step process, but adding solder in a two-step process involves additional time and may require using an additional solder machine, which can increase processing expenses. Another option is to only use EMI shields with high co-planarity tolerances, but requiring such high tolerances can increase the per-unit cost of EMI shields.

An approach that may not require such tight tolerances, and that can result in sufficient application of solder involves depositing the solder into a cavity of the circuit board and filling the cavity so that the solder extends above a surface of the circuit board, forming what this description refers to as an overfilled cavity of solder. An electronic component may then be placed on top of the solder, and heating the solder may cause the electronic component to settle into the solder. In implementations in which the portion of the electronic component that contacts the solder and that attaches to the circuit board is sized to fit within the cavity, the portion of the component that attaches to the circuit board may settle into the cavity so that at least part of the electronic component is located beneath a top surface of the circuit board.

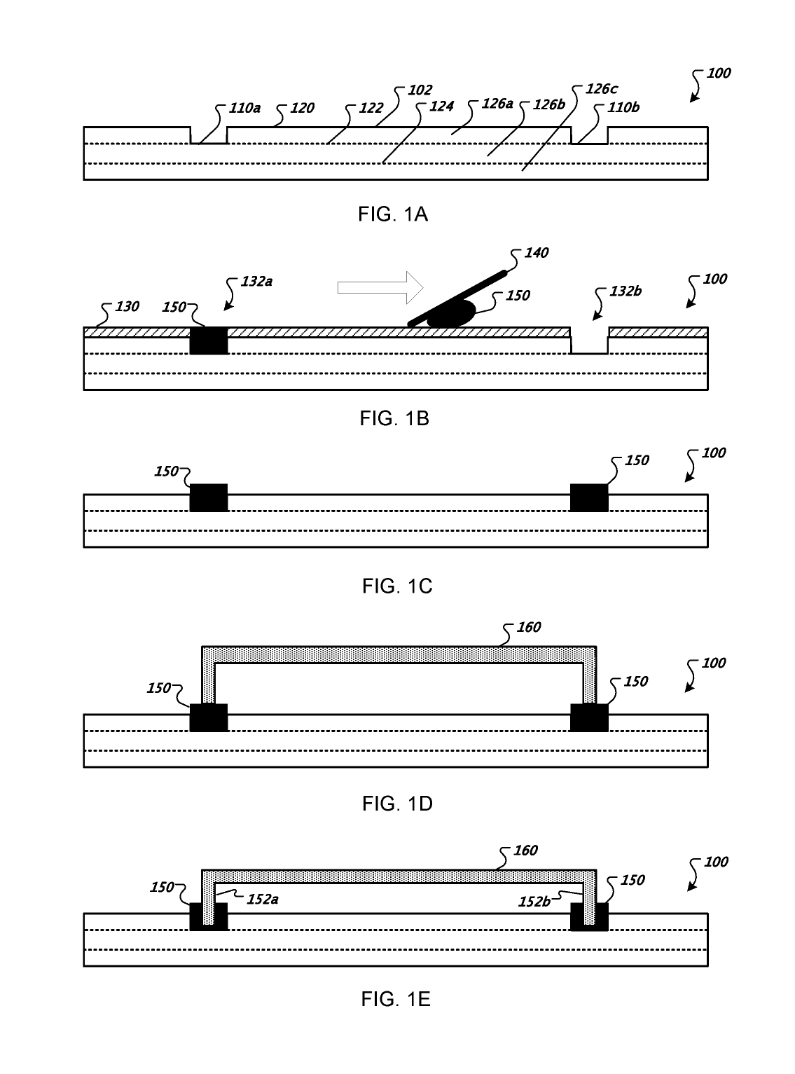

Connecting a component to a circuit board within an over-filled cavity in this manner can allow a relatively tall column of solder to be used to connect a component to a circuit board, while constraining a width of the column of solder to a width of the cavity below the surface of the circuit board (e.g., because the solder has filled the cavity) and to the width of the stencil aperture above the surface of the circuit board (e.g., because the solder filled the stencil aperture before the aperture was removed). In some examples, the width of the stencil aperture is approximately the same as the width of the cavity, but the width of the stencil aperture can also be wider or narrower than the width of the cavity. For example, the width of the stencil aperture can be narrower than the width of the cavity, so that once the component has settled into the solder, any expansion of the solder may not extend sideways beyond a width of the channel. The following discussion explains, with reference to FIGS. 1A through 4, variations of a process for attaching a component to a circuit board using an over-filled cavity of solder, and characteristics of circuit board assemblies that are created using such processes or alternative processes that would achieve similar circuit board assemblies.

FIGS. 1A-E show multiple cross-sectional views of a circuit board as a component is attached to the circuit board using an over-filled cavity of solder.

FIG. 1A shows a circuit board 100 that includes multiple cavities 110a-b formed in a surface 120 of the circuit board 110 (in some examples, cavities 110a-b represent different portions of a single cavity that surrounds region 102 of the circuit board 100). The circuit board also includes two interior layers 122 and 124. The interior layers 122 and 124 can be formed from conductive material that is processed to create paths of conductive traces on each layer (e.g., using an etching process). The conductive traces on each layer are separated from each other in the vertical direction by layers of non-conductive, insulating substrate 126a, 126b, and 126c.

In this example, cavities 110a-b terminate below a surface 120 of the circuit board 100 at interior layer 122. The cavities may be formed, for example, using a photolithographic process or a laser that removes material, and the bottom of the cavities 110a-b may be defined by a conductive trace. This conductive trace may provide a barrier that prevents the photolithographic process from etching deeper into the circuit board 100. The conductive trace can also provide an electrical interface to which one or more components may be electrically connected with solder. The depth of the cavity may be at least 0.03, 0.05 mm, 0.08, 0.1 mm, 0.12 mm, 0.15 mm, 0.2 mm, 0.3 mm, 0.4 mm, 0.5 mm, 0.6 mm, or 0.7 mm. In some examples, the cavities 110a-b may terminate at a deeper interior layer, such as the second interior layer 124. In some examples, the side walls of the cavities 110a-b may be lined with a conductive material, while in some examples the side walls of the cavities 110a-b may be defined the insulating material 126a.

FIG. 1B shows the circuit board 100 after a solder stencil 130 has been placed over a surface of the circuit board 100. The solder stencil 130 has been placed so that apertures 132a-b in the stencil are aligned with the cavities 110a-b. The apertures 132a-b may align with cavities 110a-b when the center of each of the apertures 132a-b aligns with a center of each of the cavities 110a-b. The width of the apertures 132a-b is the same as the width of the cavities 110a-b in this illustration, although the apertures 132a-b may be wider or narrower than the widths of corresponding cavities in other examples. Even in examples in which the cavities 110a-b represent different portions of a continuous cavity, the apertures 132a-b in the solder stencil 130 may represent discontinuous apertures. This difference between the continuity in the cavity and the discontinuity in the apertures can occur because the stencil may include one or more ribs separating what would have been a continuous aperture into multiple discontinuous apertures, for example, to ensure physical integrity of the stencil. As an illustration, an aperture that forms a circle or rectangle may need ribs connecting the stencil material on the outside of the circle or rectangle to the inside of the circle or rectangle to ensure that the inside of the circle or rectangle does not separate from the rest of the stencil.

In this illustration, a human or machine is wiping a squeegee 140 across a surface of the stencil 130. The wiping of the squeegee 140 across the surface of the solder stencil 130 deposits solder 150 into apertures of the stencil 130. FIG. 1B shows that solder 150 has been deposited into aperture 132a (filling cavity 110a) and will soon be deposited into aperture 132b (filling cavity 110b).

FIG. 1C shows the circuit board 100 after the solder stencil 130 has been removed from the circuit board 100. With the solder stencil 130 removed, the solder 150 protrudes out of the cavities 110a-b of the circuit board 100, such that a top surface of the solder 150 that is protruding from the cavities 110a-b is above the surface 120 of the circuit board. The solder may extend at least 0.01 mm, 0.02 mm, 0.03 mm, 0.04 mm, 0.05 mm, 0.06 mm, 0.07 mm, 0.08 mm, or more above the surface 120 of the circuit board.

FIG. 1D shows that an EMI shield 160 has been placed on top of the solder 150. In some examples, various techniques may be used to ensure that the EMI shield 160 is properly positioned and remains properly positioned, for example, through use of one or more locating pins or adhesives. In some examples, adhesive characteristics of the solder ensure that the EMI shield 160 remains properly positioned.

FIG. 1E shows the circuit board 100 after the solder 150 has been heated, for example, through a reflowing process. The heating of the solder allows the EMI shield 160 to settle into the solder 150 or be externally manipulated into the solder 150. Once the solder has cooled, a bottom surface of the side walls 162a-b of the EMI shield 160 may be positioned below a surface 120 of the circuit board 100, as illustrated in FIG. 1E. In other words, after heating, the side walls 152a-b may extend through an opening in the surface 120 of the circuit board 100 and into the cavities 110a-b, such that at least a portion of each of the side walls 152a-b is located within the cavities 110a-b. Cavities 110a-b may represent the volume that was occupied by material that has been removed from the circuit board 100.

The cross-sectional diagram that is shown in FIG. 1E illustrates how using an over-filled cavity of solder provides a sufficient amount of solder 150 in the vertical direction to attach the EMI shield 160 to the circuit board 100, while limiting an amount of side-to-side footprint of the circuit board occupied by the solder 150. Indeed, in some examples, a height of the solder 150 that is applied is greater than a width of the solder. In some examples, after the solder 150 has cooled and the EMI shield 160 has attached to the printed circuit board 100, the EMI shield 160 remains suspended above the conductive trace at the bottom of the channels 110a-b by the solder 150. In fact, the EMI shield 160 may not directly contact any portion of the circuit board 100, and rather may be attached to the circuit board 100 only via contact with solder.

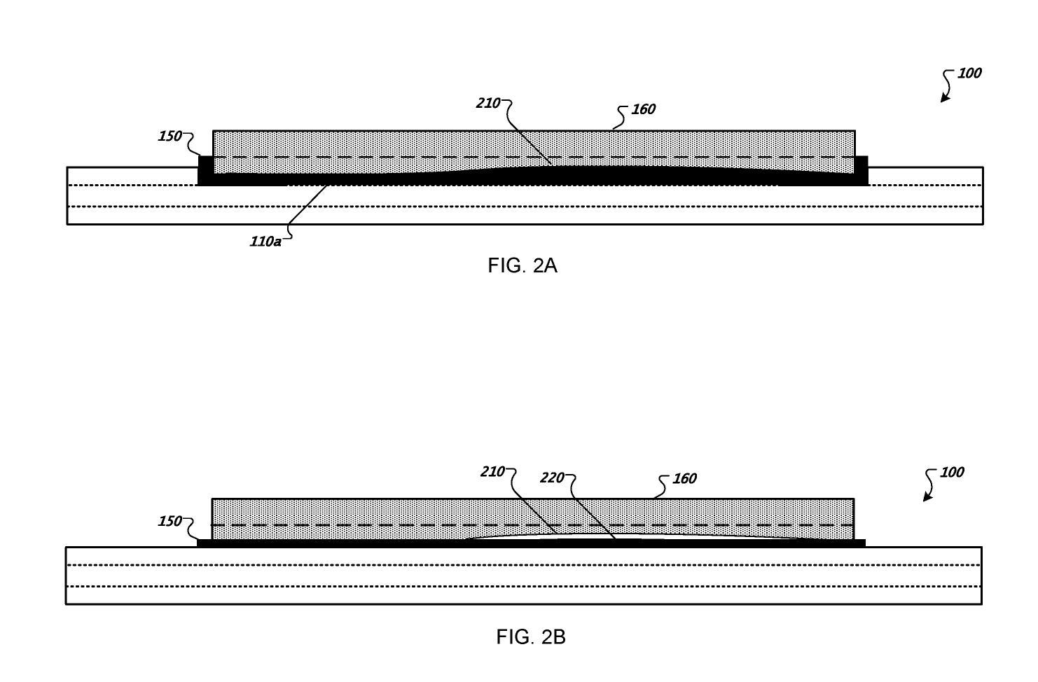

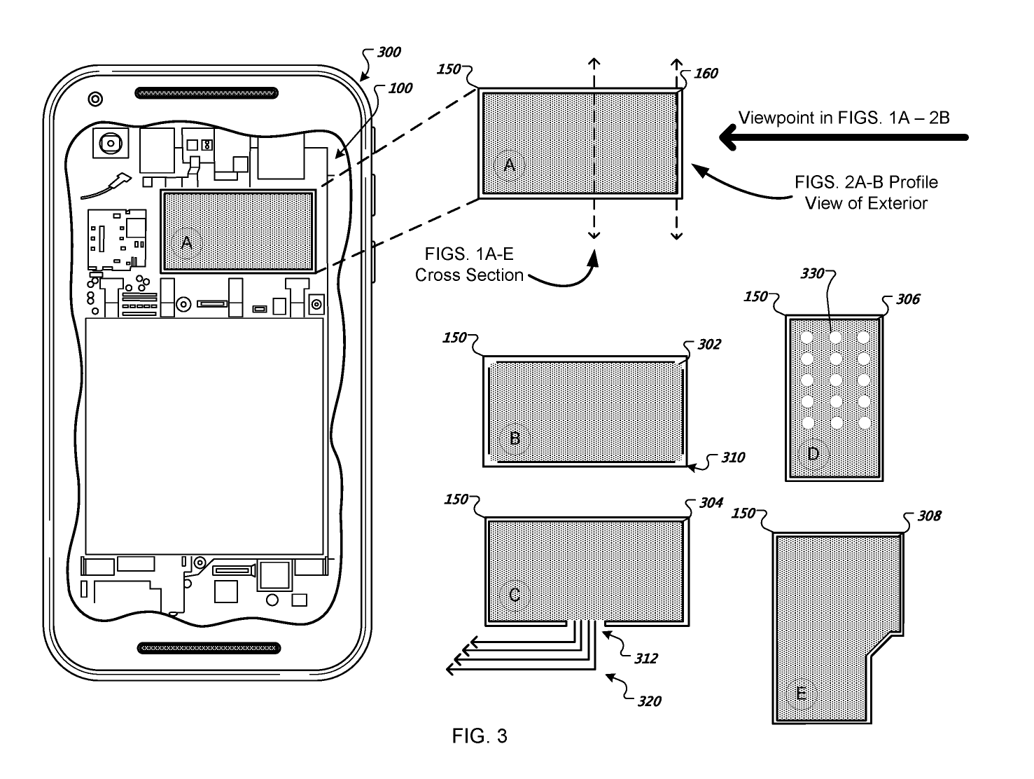

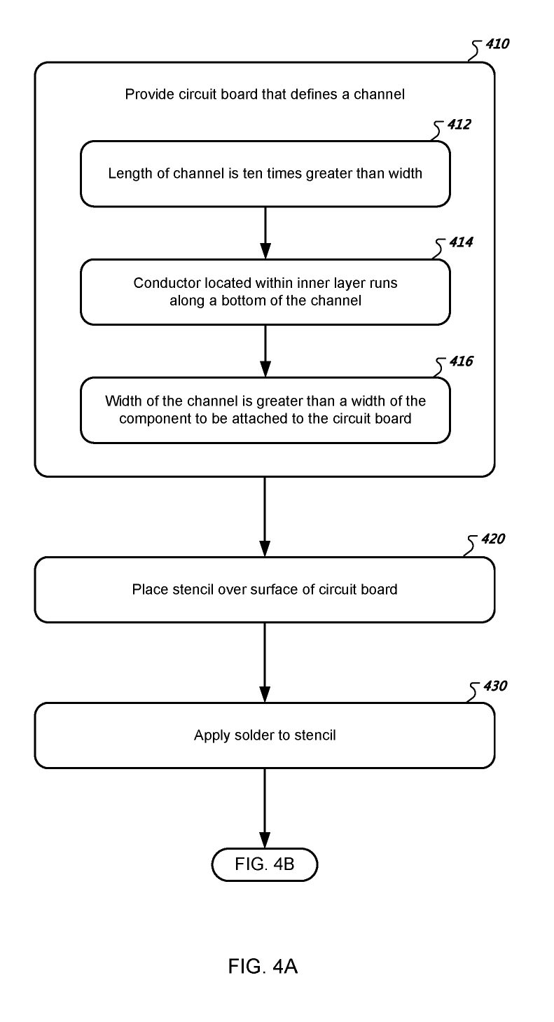

FIG. 2A shows a side-view of the EMI shield 160 after the EMI shield 160 has been attached to the circuit board 100 using an over-filled cavity of solder 150, while FIGS. 1A-E showed cross-section views of EMI shield 160. (FIG. 3 illustrates the vantage point for FIGS. 1A-E and 2A-B, with dashed lines showing the surfaces illustrated by FIGS. 1A-E and 2A-B.) FIG. 2A shows the side of the EMI shield 160, and how the bottom of that side includes an upward curve 210 and therefore is not perfectly planar (i.e., the bottom is not co-planar). Even though the bottom of the EMI shield 160 is not co-planar, solder contacts all portions of the curve 160 due to the channel being over-filled with solder 150. As such, the connection between the EMI shield 160 and the circuit board 100 is continuous along the side shown in FIG. 2A.

FIG. 2B, in contrast, shows an example in which the connection between the circuit board 100 and the same EMI shield 160 with the same upward curve 210 is discontinuous, because the EMI shield 160 was attached to the circuit board 100 without overfilling a cavity with solder. In this example, the height of solder 150 deposited onto the surface of the circuit board 100 is insufficient to contact all portions of the curve 210, which results in a discontinuous connection between the circuit board 100 and the EMI shield 160. The discontinuity illustrated in FIG. 2B could have be remedied by applying a thicker layer of solder to the circuit board 100, but as explained above, adding additional height by increasing the thickness of the stencil may increase the likelihood of “lift off” unless the stencil aperture is widened. Widening the stencil aperture, however, increases the footprint of the solder track.

FIG. 3 shows a computing device 300, which is a smartphone in this illustration. Computing device 300, however, may be another type of computing device that includes a circuit board, such as a tablet computer, a laptop computer, or a desktop computer. Computing device 300 is shown with a portion of the top surface cut away to expose circuit board 100 and multiple different electronic components attached thereto.

One such electronic component is EMI shield 160, which is illustrated in FIG. 3 both on circuit board 100 and in a blown-up view to the right of computing device 300 as implementation “A”. The view of EMI shield 160 is a top-down plan view that also shows the solder 150 that surrounds a periphery of the EMI shield 160 and that connects EMI shield 160 to the circuit board 100. This top-down view of EMI shield 160 and its associated solder track illustrates how the solder increases the footprint in the x-y dimensions allocated to the EMI shield 160 on the circuit board 100.

Various different types of EMI shields may be mounted to circuit boards using the techniques described herein. For example, implementation “B” shows an EMI shield 302 that connects to the circuit board 100 in such a manner that it leaves small openings (e.g., opening 310) at each of the corners of the EMI shield 302. These openings may be formed when sheet metal that forms the EMI shield 302 is bent to create the sidewalls of the EMI shield 302, producing an intended or unintended gap at the corners between the sidewalls. This gap may result in an EMI shield that does not perfectly seal its interior environment from its exterior environment, which can enable heat that is generated by electronic components mounted to the circuit board 100 within the interior of the EMI shield 302 to escape from the interior. The illustration of implementation “B” shows that solder 150 forms a continuous track around the periphery of the EMI shield, but the track may alternatively be discontinuous. For example, the solder track may comprise four unattached channels arranged in a rectangle, with the ends of the channels pointing toward the apparent corners of the rectangle but not touching.

Implementation “C” shows an example of an EMI shield 304 that includes a gap 312 in its sidewall (and in the solder track) through which conductive traces 320 route to connect electronic components within the EMI shield 304 to other electronic components attached at the circuit board. The presence of the gap 312 in the sidewall allows the conductive traces 320 to cross the boundary defined by the periphery of the EMI shield 304 on a surface layer of the circuit board 100 rather than such conductive traces 320 having to cross the boundary defined by the periphery of the EMI shield 304 in an interior layer of the circuit board 100.

Implementation “D” shows an example of an EMI shield 306 that includes holes (e.g., hole 330) in a horizontal surface/cover of the EMI shield 306. Such holes may enable heat to escape the interior of the EMI shield 306 and can allow outgas to escape during a solder heating reflow process.

Implementation “E” shows an example of an EMI shield 308 that has more than five sides, therefore having more than four sidewalls. In this example, EMI shield 308 includes five walls. EMI shields may have various other shapes, for example, they may be circular, have three walls, or have six walls. Common to these various examples of EMI shields is that all have sidewalls that surround any one or more electronic components attached to the circuit board 100 within an interior of the respective EMI shield, to protect such components from EMI.

Other components may be attached to a circuit board using the techniques herein. The components need not attach with lengthy walls, as illustrated with the various EMI shields shown in FIG. 3. Some components may have a large flat bottom, and the additional solder may help with structural rigidity of such components (e.g., including those that vibrate or are relatively heavy). This technique can also help reduce the overall height of a circuit board and components, since it can allow one or more components to settle at least partially into the circuit board. The techniques described herein can be used with components attaching at points sources as well, for example at the location of each pin of an integrated circuit or on either side of a two-sided component such as a resistor or capacitor.

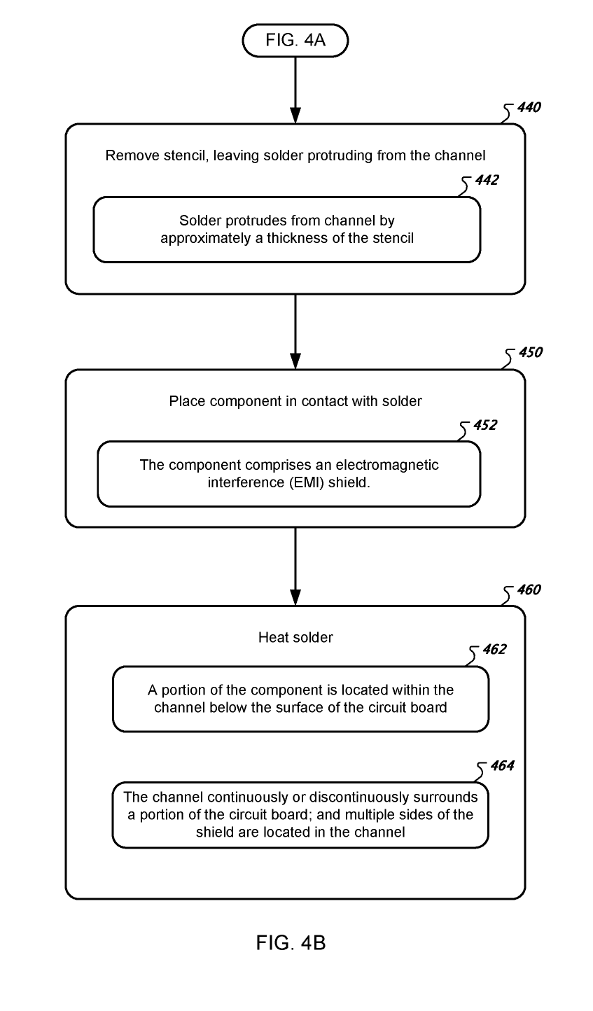

FIGS. 4A-B show a flowchart of a process for attaching a component to a circuit board using an over-filled cavity of solder.

At box 410, a circuit board that defines a channel is provided. For example, a person or machine may place circuit board 100 (see, e.g., FIG. 1A) in position for application of solder 150 to the circuit board 100. The channel may have a length that is ten times greater than a width of the channel (box 412), as illustrated by the channel 110a that is shown in FIGS. 1A-E. (An overhead view showing the length of the channel is provided in FIG. 3.) The circuit board may include an inner layer that is sandwiched between two layers of isolating, non-conductive material, with the inner layer being at least partially defined by a collection of conductive traces, sometimes formed out of copper that is deposited onto one of the isolating, non-conductive layers.

A conductive trace located within the inner layer may run along the bottom of the channel (box 414). This conductive trace may be grounded, and may provide the electrical connection to which an electronic component placed within the channel will connect. In some examples, no other conductive trace is located at the bottom of the channel. The conductive trace may define a bottom of the channel. A width of the channel may be greater than a width of a component that will be placed into the channel, at a location at which the component will attach to the circuit board (box 416). As such, the channel may form a trench within which the component will mount to the circuit board.

At box 420, a stencil is placed over a surface of the circuit board 100. The stencil may define multiple apertures into which solder will be deposited. An aperture may correspond to a shape of the channel, and placing the stencil over the surface of the circuit board 100 may include aligning the stencil so that the aperture that corresponds to the shape of the channel is aligned with the channel so that solder deposited into the aperture fills an entirety of the channel.

At box 430, solder is applied to the stencil. The solder may be applied when the apertures in the stencil are aligned with corresponding locations on the circuit board 100 at which solder is to be deposited (with some locations being on a surface of the circuit board, and at least one other location being a cavity formed in the surface of the circuit board). Applying the solder to the stencil can include wiping solder across the stencil with a squeegee, or by performing other processes by which solder may be inserted into apertures in the stencil.

At box 440, the stencil is removed, leaving solder protruding from the channel. For example, after the solder has been inserted into the stencil aperture that has a shape that corresponds to the channel, the stencil is removed to leave solder not only in the channel, but also protruding from the channel at approximately a thickness of the stencil (box 442). The protruding solder extends beyond a surface of the circuit board an amount that is approximately equal to the thickness of the stencil because, absent the stencil, the solder may have been wiped from the surface of the circuit board by a squeegee running thereacross.

At box 450, a component is placed is contact with the solder. In some examples, the component comprises an EMI shield (box 452). In other examples, the component comprises a vibrating device. The component may be placed in contact with the solder using a locating pin. The solder may also or alternatively have sufficient adhesion to hold the component in place until the solder is heated (as described below).

At box 460, the solder is heated. Heating the solder to attach components is sometimes called reflowing. Heating the solder may cause the electronic component to settle into the solder such that, upon the solder cooling, the solder may form a physical and electrical connection between the component and the circuit board 100. The settling of the component into the solder may leave at least a portion of the component located within the channel and therefore below the surface of the circuit board (box 623), as illustrated in FIG. 1E. The solder rest partially in the channel and partially wicked up the component to make a solder joint.

At box 464, the channel continuously or discontinuously surrounds a portion of the circuit board, and multiple sides of the shield are located in the channel, such that the shield at least partially surrounds the portion of the circuit board. For instance, as shown in FIG. 3, the various EMI shields 160, 302, 304, 306, and 308 are all connected to the circuit board 100 with channels filled with solder. All the channels in FIG. 3 are illustrated as continuously surrounding the portion of the circuit board that is located underneath the center of the respective EMI shield, but discontinuous surrounding is contemplated. For example, implementation “B” shown in FIG. 3 could be surrounded by a discontinuous channel that comprises four discrete channels that form a square without cavities in the circuit board 100 at the corners of the square. In this discontinuous channel example, the channel is described as surrounding the EMI shield because the channel includes a channel sub-portion for each of the four sides of the EMI shield.

In this disclosure, references to the vertical direction, up, down, or the ‘z’ direction, a dimension normal to a front surface of the circuit board. References to a footprint on a circuit board, the ‘x’ and ‘y’ dimensions, and side-to-side, represent the dimensions that define the front surface of the circuit board.

Although a few implementations have been described in detail above, other modifications are possible. Moreover, other mechanisms for performing the systems and methods described in this document may be used. In addition, the logic flows depicted in the figures do not require the particular order shown, or sequential order, to achieve desirable results. Other steps may be provided, or steps may be eliminated, from the described flows, and other components may be added to, or removed from, the described systems. Accordingly, other implementations are within the scope of the following claims.

What is claimed is:

1. A circuit-board attachment method, comprising:
providing a circuit board that defines a channel in a surface of the circuit board;
placing a stencil over the surface of the circuit board so that a slot that is in the stencil and defined by the stencil aligns with the channel in the circuit board;
applying solder to the stencil when the slot in the stencil is aligned with the channel in the circuit board to provide the solder into the slot in the stencil and the channel;
removing the stencil, leaving the solder in the channel and protruding from the channel;
placing a component in contact with the solder that is protruding from the channel; and
heating the solder to attach the component to the circuit board.

2. The circuit-board attachment method of claim 1, wherein:
the circuit board is a multi-layer circuit board that includes an interior conductive layer; and
a conductor located within the interior conductive layer runs along a bottom of the channel and defines at least a portion of the bottom of the channel.

3. The circuit-board attachment method of claim 2, wherein the conductor that runs along the bottom of the channel is grounded.

4. The circuit-board attachment method of claim 1, wherein a length of the channel is at least ten times greater than a width of the channel.

5. The circuit-board attachment method of claim 4, wherein the width of the channel is greater than a width of the component at a location of the channel at which the component attaches to the circuit board.

6. The circuit-board attachment method of claim 1, wherein removing the stencil leaves the solder protruding from the channel beyond the surface of the circuit board by approximately a thickness of the stencil.

7. The circuit-board attachment method of claim 1, wherein heating the solder attaches the component to the circuit board such that at least a portion of the component is located within the channel below the surface of the circuit board.

8. The circuit board attachment method of claim 1, wherein the component comprises an electromagnetic interference shield.

9. The circuit board attachment method of claim 8, wherein:
the channel continuously or discontinuously surrounds a region of the circuit board; and
multiple sides of the electromagnetic interference shield are located in the channel so that the electromagnetic interference shield surrounds and covers the region of the circuit board that is surrounded by the channel.

10. An electronic device assembly, comprising:
a circuit board that defines a channel in a surface of the circuit board;
a component that is attached to the circuit board, with the component being located partially in the channel and partially out of the channel; and
solder that attaches the component to the circuit board, with the solder being partially in the channel and partially protruding from the channel.

11. The electronic device assembly of claim 10, wherein:
the circuit board is a multi-layer circuit board that includes an interior conductive layer; and
a conductor located within the interior conductive layer runs along a bottom of the channel and defines at least a portion of the bottom of the channel.

12. The electronic device assembly of claim 11, wherein the conductor that runs along the bottom of the channel is grounded.

13. The electronic device assembly of claim 10, wherein a length of the channel is at least ten times greater than a width of the channel.

14. The electronic device assembly of claim 13, wherein the width of the channel is greater than a width of the component at a location of the channel at which the component attaches to the circuit board.

15. The electronic device assembly of claim 10, wherein the component comprises an electromagnetic interference shield.

16. The electronic device assembly of claim 15, wherein:
the channel continuously or discontinuously surrounds a region of the circuit board; and
multiple sides of the electromagnetic interference shield are located in the channel so that the electromagnetic interference shield surrounds and covers the region of the circuit board that is surrounded by the channel.

17. The electronic device assembly of claim 16, further comprising a computer processor that is mounted to the region of the circuit board that is surrounded by the channel and the electromagnetic interference shield.

18. The electronic device assembly of claim 10, further comprising a computer processor that is mounted to the circuit board; and
wherein the channel surrounds the computer processor and includes:
a first channel portion;
a second channel portion that is opposite and parallel to the first channel portion, the computer processor being located between the first channel portion and the second channel portion;
a third channel portion that is perpendicular to the first channel portion and perpendicular to the second channel portion; and
a fourth channel portion that is perpendicular to the first channel portion, perpendicular to the second channel portion, and parallel to the third channel portion, the computer processor being located between the third channel portion and the fourth channel portion.

19. The electronic device assembly of claim 18, wherein:
the first channel portion connects with a first end of the third channel portion and a first end of the fourth channel portion; and
the second channel portion connects with a second end of the third channel portion and a second end of the fourth channel portion.
